(19) United States
(12) Patent Application Publication
(10) Pub. No.: US 2026/0022466 A1
(43) Pub. Date: Jan. 22, 2026

(54) FILM FORMATION APPARATUS AND MAINTENANCE METHOD THEREFOR

(71) Applicant: Tokyo Electron Limited, Tokyo (JP)

(72) Inventors: Masaya ARAI, Nirasaki City (JP); Masashi TSUJIYAMA, Fuchu City (JP); Kazuyuki MAJIMA, Fuchu City (JP); Naoki WATANABE, Fuchu City (JP)

(21) Appl. No.: 19/269,202

(22) Filed: Jul. 15, 2025

(30) Foreign Application Priority Data
Jul. 17, 2024 (JP) 2024-113902

(51) Int. Cl. C23C 16/46; C23C 16/44

(52) U.S. Cl. CPC C23C 16/46; C23C 16/4407

(57) ABSTRACT

A film formation apparatus including: a processing chamber of a rectangular parallelepiped shape which accommodates a substrate; a stage heater disposed inside the processing chamber; a gas supply that supplies a raw material gas inside the processing chamber; and a liner of a cylindrical shape disposed inside the processing chamber, with both ends facing the stage heater and the gas supply respectively, wherein a maintenance door capable of opening and closing is disposed on one side surface of the processing chamber, wherein first side heaters are disposed on inner sides of respective side surfaces other than the one side surface, wherein a second side heater is installed on an inner side of the maintenance door, wherein the side heaters surround the liner when the maintenance door is closed and wherein the first side heaters are taken out from the one side surface when the maintenance door is opened.

### CROSS-REFERENCE TO RELATED APPLICATION

This application is based upon and claims the benefit of priority from Japanese Patent Application No. 2024-113902, filed on Jul. 17, 2024, the entire contents of which are incorporated herein by reference.

### TECHNICAL FIELD

The present disclosure relates to a film formation apparatus and a maintenance method for the film formation apparatus.

### BACKGROUND

A downflow-type thermal chemical vapor deposition (CVD) apparatus is known as a film formation apparatus for forming a silicon carbide (SiC) film on a surface of a wafer used as a substrate by vapor-phase growth reaction. This thermal CVD apparatus includes a stage heater disposed inside a processing chamber, a gas injector for supplying a raw material gas containing, for example, silane (SiH₄) gas or propane (C₃H₈) gas inside the processing chamber, and a cylindrical liner disposed inside the processing chamber. The liner is disposed with a central axis of the liner aligned in a vertical direction, so that openings of both ends face the stage heater and the gas injector, respectively. The gas injector supplies the raw material gas toward the wafer through an interior of the liner. A cylindrical side heater is disposed inside the processing chamber so as to surround the liner, and the side heater heats the raw material gas passing through the interior of the liner to a high temperature. The stage heater also heats the wafer to a high temperature. In this case, when the high-temperature raw material gas reaches the surface of the wafer, a SiC film is formed by the vapor-phase growth reaction (see, for example, Patent Document 1).

### PRIOR ART DOCUMENTS

### Patent Documents

Patent Document 1: Japanese Patent Publication No. 7023826

### SUMMARY

According to one embodiment of the present disclosure, there is provided a film formation apparatus including: a processing chamber of a rectangular parallelepiped shape which accommodates a substrate; a stage heater disposed inside the processing chamber; a gas supply that supplies a raw material gas inside the processing chamber; and a liner of a cylindrical shape disposed inside the processing chamber, with both ends facing the stage heater and the gas supply respectively, wherein a maintenance door capable of opening and closing is disposed on one side surface of the processing chamber, wherein first side heaters are disposed on inner sides of respective side surfaces other than the one side surface, wherein a second side heater is installed on an inner side of the maintenance door, wherein the side heaters surround the liner when the maintenance door is closed and wherein the first side heaters are taken out from the one side surface when the maintenance door is opened.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically illustrating a configuration of a substrate processing system including a film formation apparatus according to an embodiment of a technique of the present disclosure.

FIG. 2 is a longitudinal cross-sectional view schematically illustrating a configuration of the film formation apparatus in FIG. 1.

FIG. 3 is a transverse cross-sectional view schematically illustrating the configuration of the film formation apparatus in FIG. 1.

FIGS. 4A to 4C are process diagrams illustrating a method of taking out a liner and processing chamber-side heater as a maintenance method for the film formation apparatus.

FIG. 5 is a transverse cross-sectional view schematically illustrating a configuration of a modified example of the film formation apparatus.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a downflow-type thermal CVD apparatus, when film formation is repeatedly performed, by-products generated during the formation of a SiC film adhere to an inner peripheral surface of a liner, causing deterioration of a side heater over time. Therefore, for maintenance purposes, the liner or the side heater needs to be taken out of a processing chamber periodically. In particular, since the side heater has a cylindrical shape surrounding the liner, the side heater needs to be moved upward and taken out of the processing chamber so as to avoid interference with the liner. However, in such a configuration, a space for extracting the side heater needs to be secured above the processing chamber, which reduces the degree of freedom in an arrangement of the thermal CVD apparatus. In addition, since extracting the side heater above the processing chamber is a difficult and time-consuming task, this leads to an extended downtime of the thermal CVD apparatus.

Therefore, configuring the processing chamber of the thermal CVD apparatus in a rectangular parallelepiped shape and installing an independent side heater on each side surface so that the liner is surrounded by each side heater, is considered. In this case, each side surface is configured to be separable from the processing chamber, or a maintenance door for taking out the side heater is provided on each side surface. Then, each side heater can be taken out relatively easily by separating each side surface or opening the maintenance door on each side surface.

In a substrate processing system, the thermal CVD apparatus is usually connected to a transfer apparatus that transfers a substrate. In this case, one side surface of the processing chamber having the rectangular parallelepiped shape is connected to the transfer apparatus. Thus, separating the one side surface or opening the maintenance door on the one side surface while the thermal CVD apparatus is connected to the transfer apparatus, is impossible. Therefore, when taking out all the side heaters, the thermal CVD apparatus needs to be separated from the transfer apparatus and moved. However, in such a configuration, a space for moving the thermal CVD apparatus needs to be secured, which increases the footprint of the substrate processing system. In addition, since the thermal CVD apparatus is heavy, moving the thermal CVD apparatus is a difficult and time-consuming task. Therefore, this leads to an extended downtime of the substrate processing system.

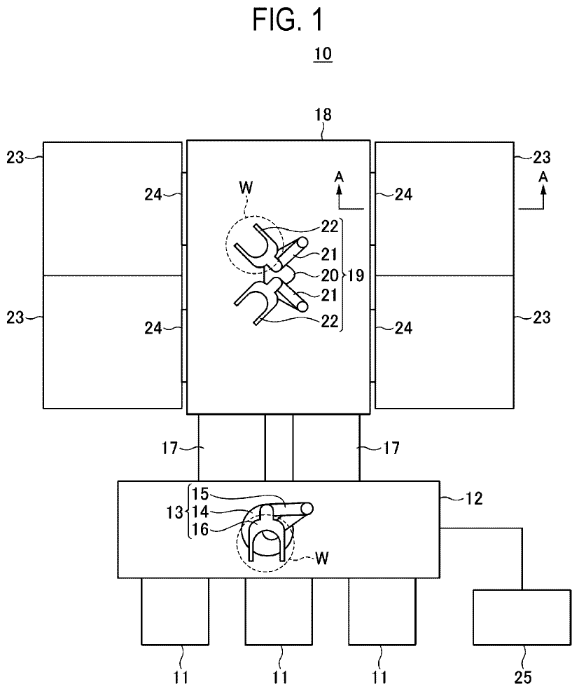

Hereinafter, an embodiment of a technique of the present disclosure will be described with reference to the drawings. FIG. 1 is a plan view schematically illustrating a configuration of a substrate processing system including a film formation apparatus according to an embodiment of the present disclosure.

In FIG. 1, a substrate processing system 10 includes three load ports 11 in which a Front Opening Unified Pod (FOUP) (not shown), which is a container for accommodating wafers W (substrates), is installed. These load ports 11 are connected to a loader chamber 12, which is a transfer chamber of the wafers W. The loader chamber 12 has a substantially rectangular parallelepiped shape, in which a transfer robot 13 for transferring the wafers W is disposed.

The transfer robot 13 includes a base 14 that is movable in a longitudinal direction of the loader chamber 12, an arm 15 that is rotatable and extendible in a horizontal plane with respect to the base 14, and a pick 16 provided at a tip end of the arm 15 to hold a wafer W. The transfer robot 13 moves the base 14, and rotates and extends/retracts the arm 15 to load and unload the wafer W to and from each FOUP and each load lock chamber 17 to be described later.

In addition, two load lock chambers 17, which function as intermediate transfer chambers for transferring the wafer W between the loader chamber 12 and a substrate transfer chamber 18 described later, are disposed on an opposite side of each load port 11, with the loader chamber 12 disposed therebetween.

In addition, the substrate transfer chamber 18 is disposed on an opposite side of the loader chamber 12, with each load lock chamber 17 disposed therebetween. The substrate transfer chamber 18 (transfer apparatus) has a substantially rectangular parallelepiped shape, in which a transfer robot 19 for transferring the wafer W is disposed. The transfer robot 19 includes a base 20 that is movable in a longitudinal direction of the substrate transfer chamber 18, an arm 21 that is rotatable and extendible in a horizontal plane with respect to the base 20, and a pick 22 provided at a tip end of the arm 21 to hold the wafer W. The transfer robot 19 moves the base 20, and rotates and extends/retracts the arm 21 to load and unload the wafer W to and from each load lock chamber 17 and each film formation apparatus 23 to be described later.

Four film formation apparatuses 23 are connected to the substrate transfer chamber 18 via gate valves 24, and the gate valves 24 control communication between the respective film formation apparatuses 23 and the substrate transfer chamber 18. Each film formation apparatus 23 performs film formation processing on the wafer W to form, for example, a SiC film on a surface of the wafer W.

The substrate processing system 10 also includes a controller 25 which controls operations of each component of the substrate processing system 10. The controller 25 includes a central processing unit (CPU), a memory, and the like, and the CPU executes film formation processing in each film formation apparatus 23 according to a recipe stored in the memory, or the like.

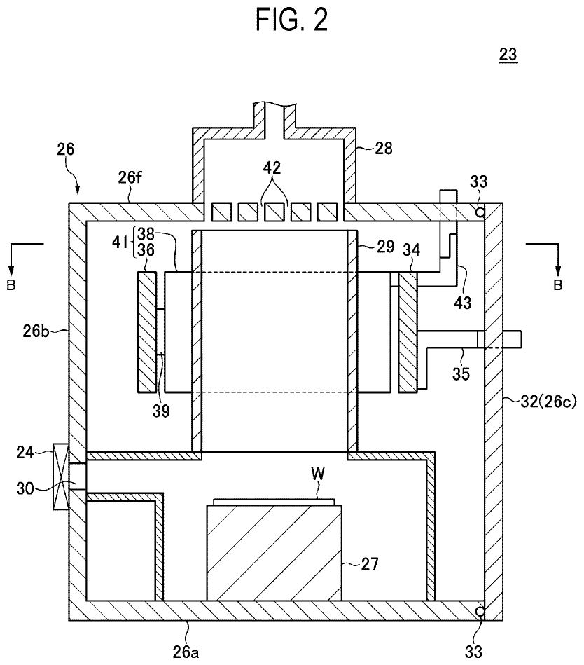

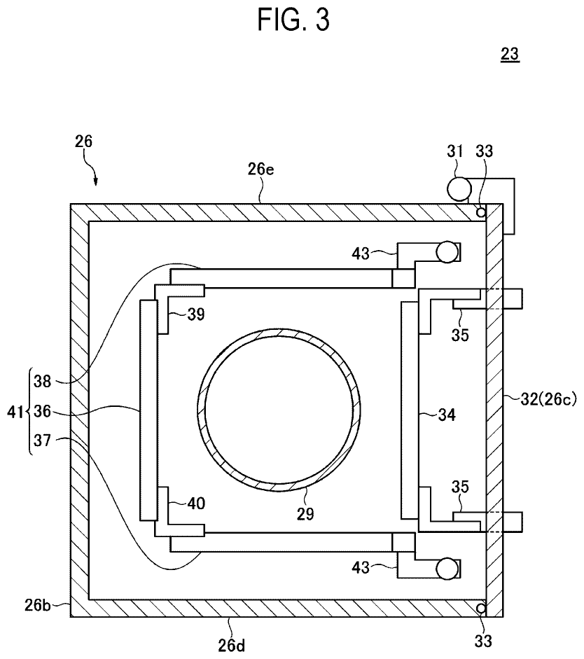

FIG. 2 is a longitudinal cross-sectional view schematically illustrating a configuration of the film formation apparatus 23 in FIG. 1 and is a cross-sectional view taken along line A-A in FIG. 1. FIG. 3 is a transverse cross-sectional view schematically illustrating the configuration of the film formation apparatus 23 in FIG. 1 and is a cross-sectional view taken along line B-B in FIG. 2.

The film formation apparatus 23 includes a processing chamber 26 having a substantially rectangular parallelepiped shape, a longitudinal direction of which is aligned in a vertical direction, for accommodating the wafer W. Inside the processing chamber 26, a stage heater 27 that functions as a stage for loading the wafer W is disposed on a bottom portion 26a of the processing chamber 26. At an upper portion of the processing chamber 26, a gas injector 28 (gas supply) that supplies a raw material gas to an interior of the processing chamber 26 is disposed so as to face the stage heater 27. Inside the processing chamber 26, a cylindrical liner 29 is disposed between the stage heater 27 and the gas injector 28. The liner 29 is disposed with a central axis of the liner 29 aligns in the vertical direction, so that an opening of a lower end faces the stage heater 27 and an opening of an upper end faces the gas injector 28. In addition, the liner 29 is made of a highly heat-resistant material, such as carbon, SiC, carbon coated with SiC, or carbon coated with tantalum carbide (TaC). An exhaust mechanism (not shown) including a vacuum pump is connected to the processing chamber 26, and the exhaust mechanism exhausts the interior of the processing chamber 26 to adjust pressure of the processing chamber 26 to a predetermined pressure.

The film formation apparatus 23 has four side surfaces. On a side surface 26b of the four side surfaces, which is connected to the substrate transfer chamber 18 via the gate valve 24, a load/unload port 30 for loading and unloading the wafer W is provided. The load/unload port 30 is opened and closed by the gate valve 24, and when the load/unload port 30 is opened, the arm 21 of the transfer robot 19 enters the interior of the processing chamber 26 via the load/unload port 30 to load and unload the wafer W.

In addition, a side surface 26c (one side surface) of the four side surfaces facing the side surface 26b constitutes a maintenance door 32 which can be opened and closed by rotating, by a hinge 31, in a horizontal direction about a rotational axis that extends in the vertical direction. When the maintenance door 32 is opened, the interior of the processing chamber 26 is opened. In order to maintain airtightness inside the processing chamber 26 when the maintenance door 32 is closed, sealing members 33 such as O-rings are disposed between the maintenance door 32 and the other side surfaces 26d and 26e, the bottom portion 26a, and a ceiling portion 26f of the processing chamber 26 that come into contact with the maintenance door 32. In addition, the side surface 26c itself does not need to constitute the maintenance door 32, and for example, a maintenance opening may be provided on the side surface 26c so that the maintenance door 32 may be disposed on the side surface 26c so as to be capable of opening and closing the maintenance opening.

On an inner side of the maintenance door 32, a door-side side heater 34 (a second side heater) utilizing electrical resistance is disposed. The door-side side heater 34 is made of a panel heater or a resistance wire that is folded and disposed to form a flat surface and is installed on the maintenance door 32 by a support member 35 which also serves as a current introduction portion for introducing a current from the outside to the door-side side heater 34. In addition, the door-side side heater 34 has an I-shape when viewed in plan, and an insulating material (not shown) is disposed between the door-side side heater 34 and the maintenance door 32.

In addition, side heaters 36 to 38 (first side heaters) utilizing electrical resistance are disposed on inner sides of the side surfaces 26b, 26d, and 26e other than the side surface 26c. Each of the side heaters 36 to 38 is also made of a panel heater or a resistance wire that is folded and disposed to form a flat surface. The side heaters 36 to 38 are integrated by being connected to each other via connection members 39 and 40 made of a conductive material, thereby constituting a processing chamber-side heater 41 having a U-shape when viewed in plan. The processing chamber-side heater 41 is installed on a maintenance door 32 side of the ceiling portion 26f by the support member 43 which also serves as the current introduction portion for introducing current from the outside. In addition, the insulating material (not shown) is also disposed between the processing chamber-side heater 41 and the side surfaces 26b, 26d, and 26e.

In the film formation apparatus 23, since the liner 29 is disposed in a central portion of the processing chamber 26, when the maintenance door 32 is closed, the liner 29 is surrounded by the door-side side heater 34 and the processing chamber-side heater 41. In this case, the door-side side heater 34 and the processing chamber-side heater 41 have a rectangular tube shape.

The stage heater 27 incorporates a heater (not shown) using electrical resistance and heats the loaded wafer W. In addition, the stage heater 27 is configured to be rotatable about a rotational axis that extends in the vertical direction, and rotates the loaded wafer W within a horizontal plane.

The gas injector 28 supplies a raw material gas for film formation including, for example, SiH₄ gas, C₃H₈ gas, hydrogen chloride (HCl) gas, or nitrogen (N₂) gas to an interior of the liner 29 via a gas supply port 42 installed at the ceiling portion 26f of the processing chamber 26. The gas injector 28 also supplies hydrogen (H₂) gas as a carrier gas of the raw material gas.

In the film formation apparatus 23, when performing film formation on the wafer W, the exhaust mechanism adjusts an internal pressure of the processing chamber 26 to, for example, 26.7 kPa, and the gas injector 28 supplies the raw material gas to the interior of the liner 29. In this case, the door-side side heater 34 or the processing chamber-side heater 41 generates heat and heats the raw material gas passing through the interior of the liner 29 toward the wafer W loaded on the stage heater 27. In addition, the stage heater 27 rotates to rotate the wafer W within a horizontal plane and simultaneously heats the wafer W. The wafer W is also heated by the radiant heat of the door-side side heater 34 or the processing chamber-side heater 41. Then, when the heated raw material gas reaches the surface of the wafer W, the SiC film is formed on the surface of the wafer W by vapor phase growth reaction.

In the film formation apparatus 23, when a film formation process is repeatedly performed, by-products generated during the formation of the SiC film adhere to an inner peripheral surface of the liner 29, resulting in a decrease in a heating efficiency of the raw material gas by the door-side side heater 34 or the processing chamber-side heater 41. Therefore, in order to clean or replace the liner 29, the liner 29 needs to be taken out of the interior of the processing chamber 26 periodically. In addition, the door-side side heater 34 or the processing chamber-side heater 41 deteriorates over time, and the heating efficiency of the raw material gas or the wafer W decrease. Therefore, similar to the liner 29, in order to repair or replace the door-side side heater 34 or the processing chamber-side heater 41, the door-side side heater 34 or the processing chamber-side heater 41 needs to be taken out of the interior of the processing chamber 26 periodically.

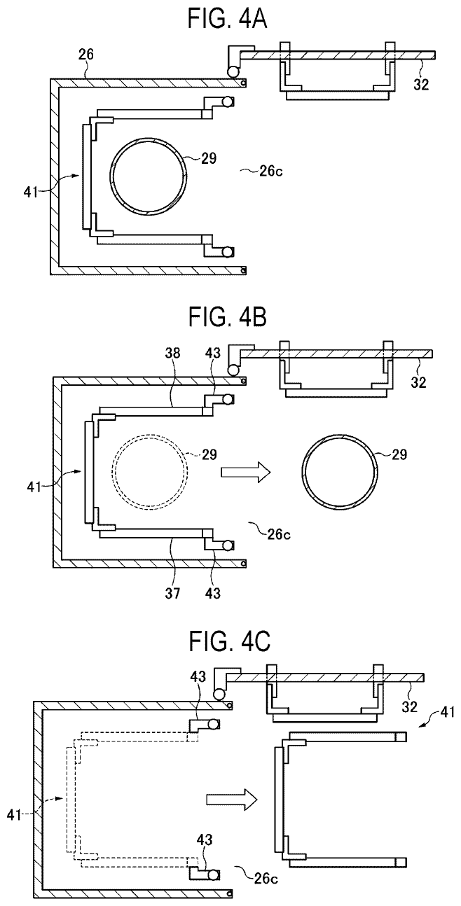

FIGS. 4A to 4C are process diagrams illustrating a method of taking out the liner 29 and the processing chamber-side heater 41 as a maintenance method for the film formation apparatus 23. First, the maintenance door 32 is opened to open the interior of the processing chamber 26. In this case, from a closed state of the maintenance door 32, it is desirable to rotate the maintenance door 32 counterclockwise by 90 degrees or more when viewed in plan (FIG. 4A). Here, since the door-side side heater 34 is installed on the maintenance door 32 by the support member 35, by opening the maintenance door 32, the door-side side heater 34 is substantially taken out of the interior of the processing chamber 26. Thus, since the door-side side heater 34 no longer exists between the side surface 26c and the liner 29, an operator can directly access the liner 29.

Next, the operator accesses the liner 29 to move the liner 29 to an opposite side of the substrate transfer chamber 18 and takes the liner 29 out from the side surface 26c (FIG. 4B). In this case, since the liner 29 no longer exists between the side surface 26c and the side heaters 36 to 38, the operator can directly access the side heaters 36 to 38.

Thereafter, the operator separates the side heaters 37 and 38 from the support member 43 and moves the side heaters 37 and 38 to the opposite side of the substrate transfer chamber 18. Here, since the side heater 36 is integrated with the side heaters 37 and 38, the operator can take the entire processing chamber-side heater 41 out from the side surface 26c in a single process by moving the side heaters 37 and 38 (FIG. 4C).

In the method of FIGS. 4A to 4C, not only the liner 29 but also the processing chamber-side heater 41 is taken out of the interior of the processing chamber 26. However, only the liner 29 may be taken out when the maintenance door 32 is opened.

According to the present embodiment, in the processing chamber 26 of the film formation apparatus 23, the liner 29 or the processing chamber-side heater 41 can be taken out simply by opening the maintenance door 32, which is the side surface 26c opposite to the side surface 26b connected to the substrate transfer chamber 18. That is, when taking out the liner 29 or the processing chamber-side heater 41, separating and moving the film formation apparatus 23 from the substrate transfer chamber 18 are not necessary. In addition, since the side heaters 36 to 38 are integrated as the processing chamber-side heater 41, taking out the side heaters 36 to 38 individually is not necessary. In addition, simply by opening the maintenance door 32, the door-side side heater 34 can be substantially taken out of the interior of the processing chamber 26. As described above, the liner 29, the door-side side heater 34, or the processing chamber-side heater 41 can be taken out of the interior of the processing chamber 26 without requiring much time, and therefore, the downtime of the substrate processing system 10 can be reduced.

According to the present embodiment, since separating and moving the film formation apparatus 23 from the substrate transfer chamber 18 as described above are not necessary, there is no need to secure a space for moving the film formation apparatus 23. In addition, the support member 35 of the door-side side heater 34 is installed on the maintenance door 32, and the support member 43 of the processing chamber-side heater 41 is installed on the maintenance door 32 side of the ceiling portion 26f. The support member 43 may also be installed on the maintenance door 32 side of the bottom portion 26a. That is, the current introduction portions of the door-side side heater 34 and the processing chamber-side heater 41 are concentrated and disposed on the maintenance door 32 (side surface 26c) side of the processing chamber 26. In addition, since the side heater 36 is integrated with the side heaters 37 and 38, providing a current introduction portion for the side heater 36 is not necessary. As a result, the current introduction portion does not protrude toward the side surfaces 26b, 26e, and 26d, so that the processing chamber 26 of the film formation apparatus 23 can be prevented from expanding in a horizontal direction. Therefore, an increase in the footprint of the substrate processing system 10 can be prevented.

However, since a frequency of the decreased heating efficiency of the raw material gas caused by by-products adhering to the inner peripheral surface of the liner 29 and increased defects caused by particles, which are generated from these by-products and adhere to the wafer W, is higher than a frequency of deterioration of the door-side side heater 34 or the processing chamber-side heater 41 over time, there is a demand for taking out only the liner 29. In the present embodiment, when the maintenance door 32 is opened, only the liner 29 can be taken out without performing the separation work of the door-side side heater 34 and the processing chamber-side heater 41, so that the above-described demand can be met. As a result, a frequency of replacement or manufacturing of the liner 29 can be improved, and further, the deterioration of the heating efficiency of the raw material gas can be suppressed.

While preferred embodiments of the present disclosure have been described hereinabove, the present disclosure is not limited to the above-described embodiments and various modifications and changes may be made without departing from the spirit and scope of the disclosure.

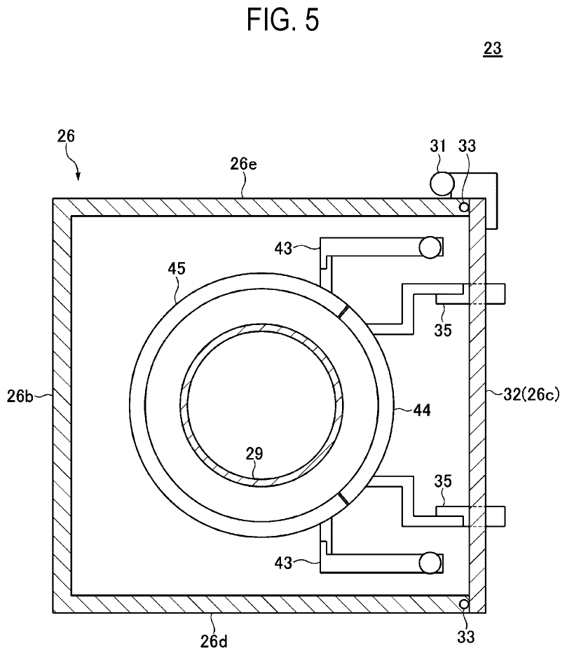

For example, in the film formation apparatus 23, the side heaters 36 to 38 and the door-side side heater 34 are configured such that the door-side side heater 34 and the processing chamber-side heater 41, surrounding the liner 29, have a rectangular tube shape when the maintenance door 32 is closed. However, each heater may be configured such that the heaters surrounding the liner 29 have a cylindrical shape when the maintenance door 32 is closed. In this case, as shown in FIG. 5, a door-side side heater 44 having an arc shape when viewed in plan is disposed on the inner side of the maintenance door 32, and a processing chamber-side heater 45 having a C-shape when viewed in plan is disposed on the inner sides of the side surfaces 26b, 26d, and 26e.

In addition, the side heaters 36 to 38 may not be integrated and may be installed by supporting members on the side surfaces 26b, 26d, and 26e, respectively. However, even in this case, it is desirable that the current introduction portions of the side heaters 36 to 38 are concentrated and disposed on the maintenance door 32 (side surface 26c) side.

According to a technique of the present disclosure in some embodiments, downtime can be reduced.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A film formation apparatus, comprising:
a processing chamber of a rectangular parallelepiped shape configured to accommodate a substrate;
a stage heater disposed inside the processing chamber;
a gas supply configured to supply a raw material gas for film formation to an interior of the processing chamber; and
a liner of a cylindrical shape disposed inside the processing chamber,
wherein the liner is disposed with openings of both ends facing the stage heater and the gas supply, respectively,
wherein a maintenance door configured to be capable of opening and closing is disposed on one side surface of the processing chamber,
wherein first side heaters are disposed on inner sides of respective side surfaces other than the one side surface,
wherein a second side heater is installed on an inner side of the maintenance door,
wherein the first side heaters and the second side heater surround the liner when the maintenance door is closed, and
wherein the first side heaters are configured to be taken out from the one side surface when the maintenance door is opened.

2. The film formation apparatus of claim 1, wherein the first side heaters disposed on the inner sides of the side surfaces are integrated.

3. The film formation apparatus of claim 1, wherein the liner is configured to be taken out from the one side surface when the maintenance door is opened.

4. The film formation apparatus of claim 1, wherein the film formation apparatus is installed to a transfer apparatus, and
wherein the one side surface on which the maintenance door is disposed is a side surface opposite to a side surface connected to the transfer apparatus.

5. The film formation apparatus of claim 1, wherein current introduction portions of the first side heaters and the second side heater are disposed on the maintenance door side of the processing chamber.

6. A maintenance method for a film formation apparatus,
the film formation apparatus including:
a processing chamber of a rectangular parallelepiped shape configured to accommodate a substrate;
a stage heater disposed inside the processing chamber;
a gas supply configured to supply a raw material gas for film formation to an interior of the processing chamber; and
a liner of a cylindrical shape disposed inside the processing chamber,
wherein the liner is disposed with openings of both ends facing the stage heater and the gas supply, respectively,
wherein a maintenance door configured to be capable of opening and closing is disposed on one side surface of the processing chamber,
wherein first side heaters are disposed on inner sides of respective side surfaces other than the one side surface,
wherein a second side heater is installed on an inner side of the maintenance door, and
wherein the first side heaters and the second side heater surround the liner when the maintenance door is closed,
the maintenance method comprising taking the first side heaters out from the one side surface by opening the maintenance door.

7. The maintenance method of claim 6, further comprising taking the liner out from the one side surface by opening the maintenance door.
